(19) United States
(12) Patent Application Publication
(10) Pub. No.: US 2025/0294683 A1
(43) Pub. Date: Sep. 18, 2025

(54) CIRCUIT BOARD

(71) Applicant: TAIYO YUDEN CO., LTD., Tokyo (JP)

(72) Inventor: Ayumi SHIROTA, Tokyo (JP)

(73) Assignee: TAIYO YUDEN CO., LTD., Tokyo (JP)

(21) Appl. No.: 19/224,194

(22) Filed: May 30, 2025

Related U.S. Application Data
(63) Continuation of application No. PCT/JP2023/046245, filed on Dec. 22, 2023.

(30) Foreign Application Priority Data
Dec. 27, 2022 (JP) 2022-210677

(51) Int. Cl. H05K 1/18; H01G 4/012; H01G 4/30

(52) U.S. Cl. CPC H05K 1/181; H01G 4/30; H01G 4/012; H05K 2201/10015; H05K 2201/10522

(57) ABSTRACT

First and second ceramic electronic devices are arranged on a mounting surface in a state in which respective height directions are orthogonal to the mounting surface, length directions of the first and second ceramic electronic devices are in the same direction, and one of a first external electrode and a second external electrode of the first multilayer ceramic electronic device and one of a first external electrode and a second external electrode of the second multilayer ceramic electronic device are adjacent to each other along a length direction and opposed to each other along the length direction. A height dimension of the first multilayer ceramic electronic device is 1.3 times or more larger than a width dimension or a length dimension thereof. A height dimension of the second multilayer ceramic electronic device is 1.3 times or more larger than a width dimension or a length dimension thereof.

### CROSS-REFERENCE TO RELATED APPLICATION

This application is a continuation application of PCT/JP2023/046245 filed on Dec. 22, 2023, which claims priority to Japanese Patent Application No. 2022-210677 filed on Dec. 27, 2022, the contents of which are herein wholly incorporated by reference.

### FIELD

A certain aspect of the present invention relates to a circuit board.

### BACKGROUND

In recent years, various electronic devices have become smaller and more functional, and the mounting area of electronic devices, including multilayer ceramic electronic devices, on circuit boards tends to be reduced. On the other hand, there is a demand for multilayer ceramic electronic devices to have more layers. In order to meet such demands, device structures have been proposed to achieve higher density mounting and more layers (see, for example, Japanese Patent Application Publication No. 2020-031152 hereinafter referred to as Patent Document 1). In multilayer ceramic electronic devices, the mounting area on a circuit board can be determined by the length and width dimensions of the multilayer ceramic electronic device. Patent Document 1 proposes making the height dimension of the multilayer ceramic electronic device, that is, the dimension perpendicular to the mounting surface of the circuit board, larger than the length or width dimension to make it taller. Tall multilayer ceramic electronic devices are suitable for multilayering.

### SUMMARY OF THE INVENTION

According to an aspect of the present invention, there is provided a circuit board including: a board; and a plurality of multilayer ceramic electronic devices mounted on a mounting surface of the board, wherein when a direction along a first axis is defined as a height direction, a direction along a second axis orthogonal to a direction along the first axis is defined as a width direction, and a direction along a third axis orthogonal to the direction along the first axis and the direction along the second axis is defined as a length direction, of the plurality of multilayer ceramic electronic devices, at least a first multilayer ceramic electronic device and a second multilayer ceramic electronic device have a first external electrode at a first end in the length direction and a second external electrode at a second end in the length direction, wherein a height dimension of the first multilayer ceramic electronic device is 1.3 times or more larger than a width dimension or a length dimension of the first multilayer ceramic electronic device, and a height dimension of the second multilayer ceramic electronic device is 1.3 times or more larger than a width dimension or a length dimension of the second multilayer ceramic electronic device, and wherein the first ceramic electronic device and the second multilayer ceramic electronic device are arranged on the mounting surface in a state in which the respective height directions of the first ceramic electronic device and the second multilayer ceramic electronic device are orthogonal to the mounting surface, the length directions of the first ceramic electronic device and the second multilayer ceramic electronic device are in the same direction, and one of the first external electrode and the second external electrode of the first multilayer ceramic electronic device and one of the first external electrode and the second external electrode of the second multilayer ceramic electronic device are adjacent to each other along the length direction and opposed to each other along the length direction.

### BRIEF DESCRIPTION OF THE DRAWINGS

FIG. 1A is a front view of a circuit board of a first embodiment;

FIG. 1B is a plan view thereof;

FIG. 1C is an equivalent circuit diagram of a circuit board illustrated in FIG. 1A and FIG. 1B;

FIG. 1D is an explanatory diagram illustrating first and second multilayer ceramic capacitors mounted on a circuit board of a first embodiment, viewed from the first multilayer ceramic capacitor side along their length direction;

FIG. 1E is an explanatory diagram illustrating first and second multilayer ceramic capacitors mounted on a circuit board of a first embodiment, moved relatively in their width direction;

FIG. 2 is a perspective view of first and second multilayer ceramic capacitors used in a circuit board of a first embodiment;

FIG. 3A to FIG. 3D are a four-sided view of the first and second multilayer ceramic capacitors used in a circuit board of a first embodiment;

FIG. 4 is a cross-sectional view taken along a line A1-A1 in FIG. 2 of a first multilayer ceramic capacitor used in a circuit board of a first embodiment;

FIG. 5A is a cross-sectional view taken along a line A2-A2 in FIG. 2 of a first multilayer ceramic capacitor used in a circuit board of a first embodiment;

FIG. 5B is a cross-sectional view taken along a line A3-A3 in FIG. 2 of a first multilayer ceramic capacitor used in a circuit board of a first embodiment;

FIG. 6 is a perspective view of a circuit board of a first embodiment, illustrating a partial cross-section of a first multilayer ceramic capacitor taken along a line A1-A1 in FIG. 2, and a partial cross-section of a second multilayer ceramic capacitor in a similar manner;

FIG. 7A is a side view of a circuit board of a second embodiment;

FIG. 7B is a plan view of a circuit board of a second embodiment;

FIG. 7C is a plan view of a circuit board of a third embodiment;

FIG. 8 is a cross-sectional view of a first multilayer ceramic capacitor used in a circuit board of a fourth embodiment, taken along a line segment corresponding to a line A1-A1 in FIG. 2;

FIG. 9A is a cross-sectional view of a first multilayer ceramic capacitor used in a circuit board of a fourth embodiment, taken along a line segment corresponding to line A2-A2 in FIG. 2;

FIG. 9B is a cross-sectional view of a first multilayer ceramic capacitor used in a circuit board of a fourth embodiment, taken along a line segment corresponding to line A3-A3 in FIG. 2;

FIG. 10 is a perspective view of a circuit board of a fourth embodiment, illustrating a first multilayer ceramic capacitor and a second multilayer ceramic capacitor in partial cross-section;

FIG. 11 is a partially exploded view of a ceramic body provided in a first multilayer ceramic capacitor in a fifth embodiment;

FIG. 12 is a partially exploded view of a ceramic body provided in a first multilayer ceramic capacitor in a modified example of a fifth embodiment;

FIG. 13 is an oblique view of a circuit board illustrating partial cross sections of a first multilayer ceramic capacitor and a second multilayer ceramic capacitor of a modified example of a fifth embodiment;

FIG. 14A is a side view of a circuit board of a comparative example;

FIG. 14B is a plan view thereof; and

FIG. 15A and FIG. 15B are schematic diagrams illustrating how a first multilayer ceramic capacitor of a comparative example tilts.

### DETAILED DESCRIPTION

If a multilayer ceramic electronic device that is large in height and densely mounted is tilted, the multilayer ceramic electronic device may come into contact with other electronic devices mounted around the multilayer ceramic electronic device, potentially causing a short circuit.

Below, a circuit board according to an embodiment of the present invention will be described with reference to the attached drawings. In the drawings, the dimensions, ratios, or the like of each part may not be illustrated to be completely consistent with the actual ones. In addition, for convenience of drawing, some details may be omitted or components themselves may be omitted in some drawings. In addition, the drawings indicate X-axis, Y-axis, and Z-axis which are mutually orthogonal as appropriate. The X-axis, Y-axis, and Z-axis define a fixed coordinate system fixed with respect to the circuit board 0. In the following description, the Z-axis direction corresponds to the direction along the first axis, and the Y-axis direction corresponds to the direction along the second axis. The X-axis direction corresponds to the direction along the third axis.

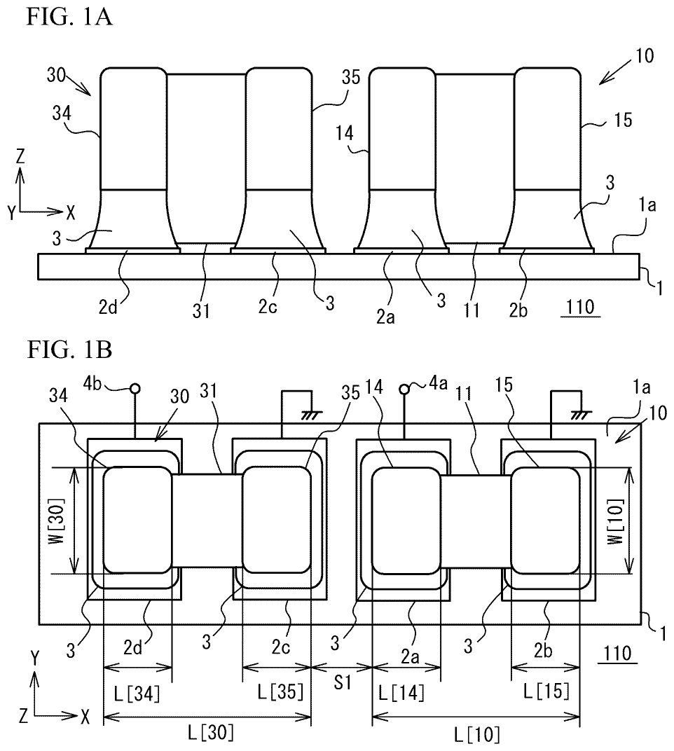

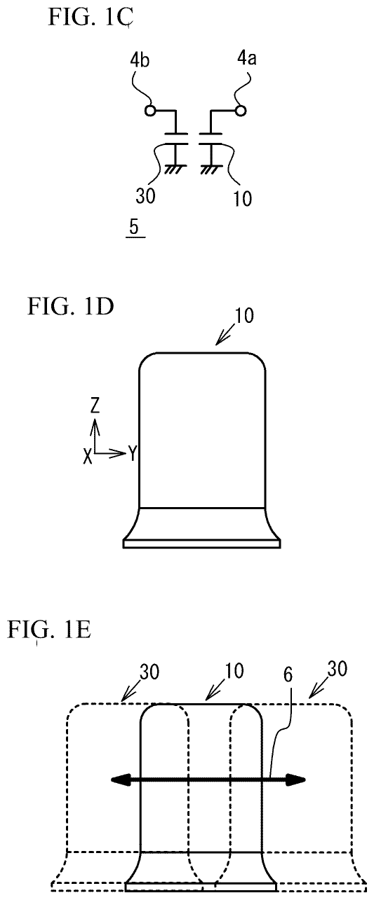

### First Embodiment

[Circuit board] First, the schematic configuration of a circuit board 110 according to the first embodiment will be described with reference to FIG. 1A to FIG. 1C. FIG. 1A is a front view of the circuit board 110 according to the first embodiment. FIG. 1B is a plan view of the circuit board 110. FIG. 1C is an equivalent circuit diagram of the circuit board 110 of the first embodiment. The circuit board 110 includes a printed wiring board 1 as a board, a first multilayer ceramic capacitor (MLCC: Multi Layered Ceramic Capacitor) 10, and a second multilayer ceramic capacitor 30. In this embodiment, the first multilayer ceramic capacitor 10 and the second multilayer ceramic capacitor 30 are the same, but are given different reference numbers for convenience of explanation. The first multilayer ceramic capacitor 10 includes a first external electrode 14 and a second external electrode 15. Similarly, the second multilayer ceramic capacitor 30 includes a first external electrode 34 and a second external electrode 35.

In the circuit board 110, it is required to avoid a short circuit between the first external electrode 14 and the second external electrode 15 of the first multilayer ceramic capacitor 10 and the first external electrode 34 and the second external electrode 35 of the second multilayer ceramic capacitor 30. Specifically, for example, it is required to avoid a short circuit between the first external electrode 14 of the first multilayer ceramic capacitor 10 and the first external electrode 34 or the second external electrode 35 of the second multilayer ceramic capacitor 30. Also, for example, it is required to avoid a short circuit between the second external electrode 15 of the first multilayer ceramic capacitor 10 and the first external electrode 34 or the second external electrode 35 of the second multilayer ceramic capacitor 30.

In the circuit configuration of this embodiment, as illustrated in an equivalent circuit 5 in FIG. 1C, one external electrode of the first multilayer ceramic capacitor 10 is grounded, and the other external electrode is input via the first terminal 4a. Also, one external electrode of the second multilayer ceramic capacitor 30 is grounded, and the other external electrode is input via the second terminal 4b. For this reason, in this embodiment, it is required to avoid contact between the grounded external electrode of the first multilayer ceramic capacitor 10 and the external electrode to which the second terminal 4b of the second multilayer ceramic capacitor 30 is connected. It is also required to avoid contact between the external electrode to which the first terminal 4a of the first multilayer ceramic capacitor 10 is connected and the grounded external electrode of the second multilayer ceramic capacitor 30. It is also required to avoid contact between the external electrode to which the first terminal 4a of the first multilayer ceramic capacitor 10 is connected and the external electrode to which the second terminal 4b of the second multilayer ceramic capacitor 30 is connected. However, this circuit configuration is only an example, and the combination of external electrodes whose contact should be avoided differs depending on the circuit configuration.

The printed wiring board 1 is provided with a first land 2a, a second land 2b, a third land 2c, and a fourth land 2d. The second land 2b and the third land 2c are grounded. The first land 2a is provided with a first terminal 4a. The fourth land 2d is provided with a second terminal 4b.

The first external electrode 14 of the first multilayer ceramic capacitor 10 is disposed on the first land 2a on which the first terminal 4a is disposed. The second external electrode 15 of the first multilayer ceramic capacitor 10 is disposed on the second land 2b, which is grounded. The second external electrode 35 of the second multilayer ceramic capacitor 30 is disposed on the third land 2c, which is grounded. And the first external electrode 34 of the second multilayer ceramic capacitor 30 is disposed on the fourth land 2d on which the second terminal 4b is disposed.

For this reason, in this embodiment, it is required to avoid contact between the first external electrode 14 of the first multilayer ceramic capacitor 10 and the second external electrode 35 of the second multilayer ceramic capacitor 30. Furthermore, it is required to avoid contact between the second external electrode 15 of the first multilayer ceramic capacitor 10 and the first external electrode 34 of the second multilayer ceramic capacitor 30. Furthermore, it is required to avoid contact between the first external electrode 14 of the first multilayer ceramic capacitor 10 and the first external electrode 34 of the second multilayer ceramic capacitor 30.

Note that each external electrode is fixed to the respective arranged land by a solder fillet 3. As a result, the first multilayer ceramic capacitor 10 and the second multilayer ceramic capacitor 30 are mounted on a mounting surface la of the printed wiring board 1.

The first multilayer ceramic capacitor 10 and the second multilayer ceramic capacitor 30 are mounted on the printed wiring board 1 so that their respective height directions are perpendicular to the mounting surface 1a.

The first multilayer ceramic capacitor 10 and the second multilayer ceramic capacitor 30 are mounted on the mounting surface 1a in a state in which they are adjacent to each other in the X-axis direction, with the first external electrode 14 of the first multilayer ceramic capacitor 10 and the second external electrode 35 of the second multilayer ceramic capacitor 30 facing each other along the X-axis direction. In this description, the adjacent state refers to a state in which no other components are mounted between the first multilayer ceramic capacitor 10 and the second multilayer ceramic capacitor 30.

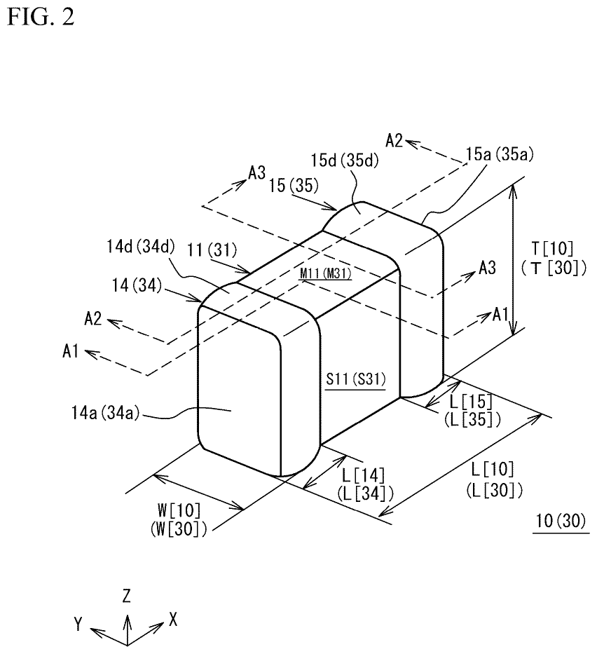

The first multilayer ceramic capacitor 10 and the second multilayer ceramic capacitor 30 may be mounted in a state rotated 180°. The positional relationship between the first multilayer ceramic capacitor 10 and the second multilayer ceramic capacitor 30 will be described in more detail later.

<Dimensional notation of the first multilayer ceramic capacitor and the second multilayer ceramic capacitor> Here, the notation of the dimensions of each part of the first multilayer ceramic capacitor 10 will be described with reference to FIG. 2, which is a perspective view of the first multilayer ceramic capacitor 10. The X-axis dimension of the first multilayer ceramic capacitor 10, that is, the length, is expressed as L[10], and the Y-axis dimension, that is, the width, is expressed as W[10]. The Z-axis dimension, that is, the height, is T[10]. The X-axis dimension of the first external electrode 14, that is, the length, is expressed as L[14]. Similarly, the X-axis dimension of the second external electrode 15, that is, the length, is expressed as L[15]. Note that the ceramic body 11, which will be described later, is exposed between the first external electrode 14 and the second external electrode 15.

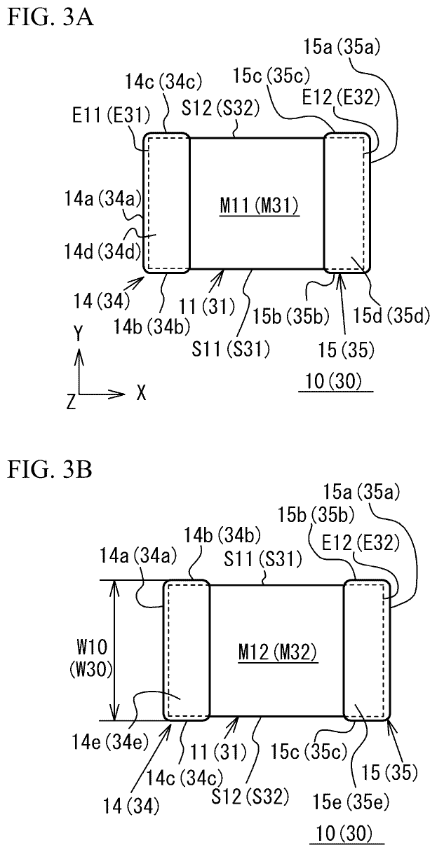

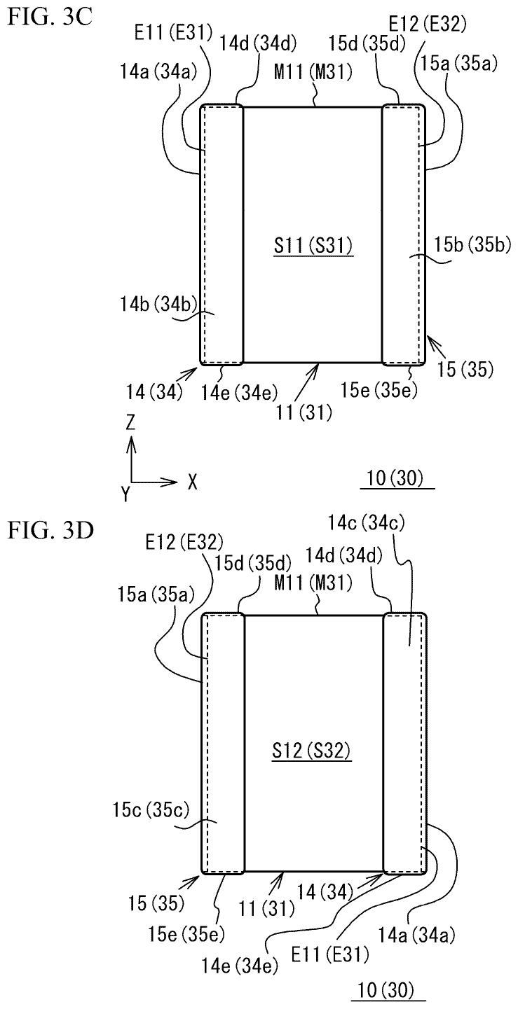

The second multilayer ceramic capacitor 30 is similarly notated. The dimension in the X-axis direction of the second multilayer ceramic capacitor 30, that is, the length, is expressed as L[30], and the dimension in the Y-axis direction, that is, the width, is expressed as W[30]. The dimension in the Z-axis direction, that is, the height, is expressed as T[30]. The dimension in the X-axis direction of the first external electrode 34, that is, the length, is expressed as L[34]. Similarly, the dimension in the X-axis direction of the second external electrode 35, that is, the length, is expressed as L[35]. Note that the ceramic body 31, which will be described later, is exposed between the first external electrode 34 and the second external electrode 35.

<First Multilayer Ceramic Capacitor> Next, the first multilayer ceramic capacitor 10 will be described in detail with reference to FIG. 2 and FIG. 3A to FIG. 3D. FIG. 3A to FIG. 3D are four-sided views of the first multilayer ceramic capacitor 10. The first multilayer ceramic capacitor 10 and the second multilayer ceramic capacitor 30 are identical and have roughly the same external shape, so reference numerals indicating the components of both are used in FIG. 2 and FIG. 3A to FIG. 3D.

<External Shape> First, the external shape of the first multilayer ceramic capacitor 10 will be described.

The first multilayer ceramic capacitor 10 includes a ceramic body 11, the first external electrode 14, and the second external electrode 15. The ceramic body 11 is configured as a hexahedron having first and second main faces M11, M12 orthogonal to the Z axis, first and second end faces E11, E12 orthogonal to the X axis, and first and second side faces S11, S12 orthogonal to the Y axis. Note that the “hexahedron” may be substantially hexahedral, and for example, the ridges connecting the faces of the ceramic body 11 may be rounded.

The main faces M11, M12, end faces E11, E12, and side faces S11, S12 of the ceramic body 11 are all configured as flat surfaces. The flat surface according to this embodiment does not have to be strictly planar as long as it is recognized as flat when viewed overall, and includes, for example, a surface having minute irregularities or a gently curved shape existing within a predetermined range.

The first multilayer ceramic capacitor 10 is a tall type having a height T[10] of 1.3 times or more the width W[10]. In the first multilayer ceramic capacitor 10, the height [T10] is increased to increase the capacity by increasing the number of layers. It is desirable to set the height T[10] to 1.5 times or more the width W[10]. The height T[10] can be set to, for example, 1.6 times or 1.7 times the width W[10], or even higher. This allows the first multilayer ceramic capacitor 10 to have a larger capacity. The same applies to the second multilayer ceramic capacitor 30.

In this embodiment, the condition for height T[10] is defined by the ratio to width W[10], but the condition for height T[10] may be set based on its relationship with length L[10] instead of width W[10]. In other words, the first multilayer ceramic capacitor 10 may be a tall type in which height T[10] is 1.3 times or more larger than length W[10]. Also, height T[10] may be 1.5 times or more larger than length L[10].

In the first multilayer ceramic capacitor 10, the dimension of the ceramic body 11 in the X-axis direction may be larger than the dimension in the Y-axis direction, and may be smaller than the dimension in the Z-axis direction. In the first multilayer ceramic capacitor 10, the dimensions of the ceramic body 11 in the three axial directions can be determined arbitrarily within the range that satisfies the above conditions.

In the first multilayer ceramic capacitor 10 of this embodiment, for example, the length L[10] may be set to 0.2 mm or more and 1.2 mm or less, and the width W[10] may be set to 0.1 mm or more and 0.7 mm or less. Also, the height T[10] may be set to 0.15 mm or more and 1.0 mm or less. The height T[10], the width W[10], and the length L[10] are all maximum dimensions of the first multilayer ceramic capacitor 10 in each direction.

The first external electrode 14 has a first surface portion 14a that covers the end face E11 of the ceramic body 11. The first external electrode 14 has a second surface portion 14b extending from the first surface portion 14a to the side face S11, and a third surface portion 14c extending to the side face S12. Furthermore, the first external electrode 14 has a fourth surface portion 14d extending from the first surface portion 14a to the main face M11, and a fifth surface portion 14e extending to the main face M12.

The second external electrode 15 has a first surface portion 15a covering the end face E12 of the ceramic body 11. The second external electrode 15 has a second surface portion 15b extending from the first surface portion 15a to the side face S11, and a third surface portion 15c extending to the side face S12. Furthermore, the second external electrode 15 has a fourth surface portion 15d extending from the first surface portion 15a to the main face M11, and a fifth surface portion 15e extending to the main face M12.

Here, the second surface portions 14b, 15b, the third surface portions 14c, 15c, the fourth surface portions 14d, 15d, and the fifth surface portions 14e, 15e correspond to extension portions.

The external electrodes 14, 15 have U-shaped cross sections parallel to the X-Z plane and the X-Y plane. The shape of the external electrodes 14, 15 is not limited to the example illustrated in the drawings.

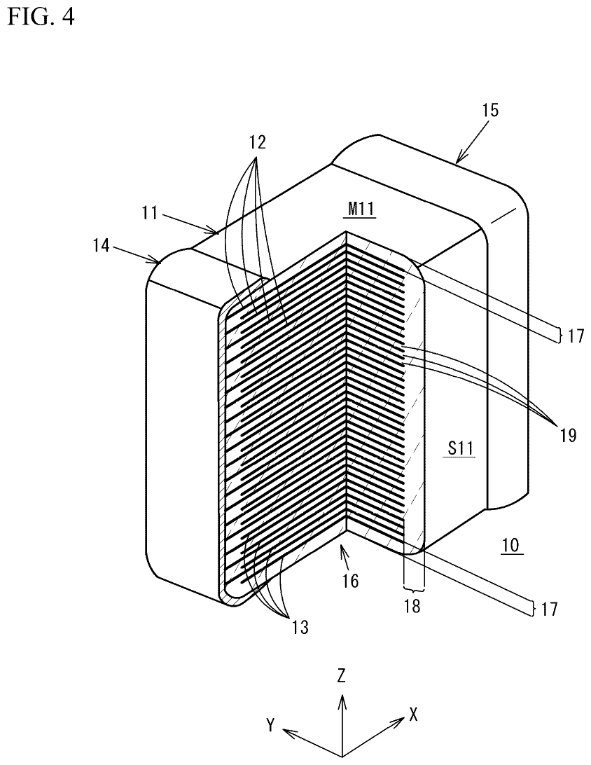

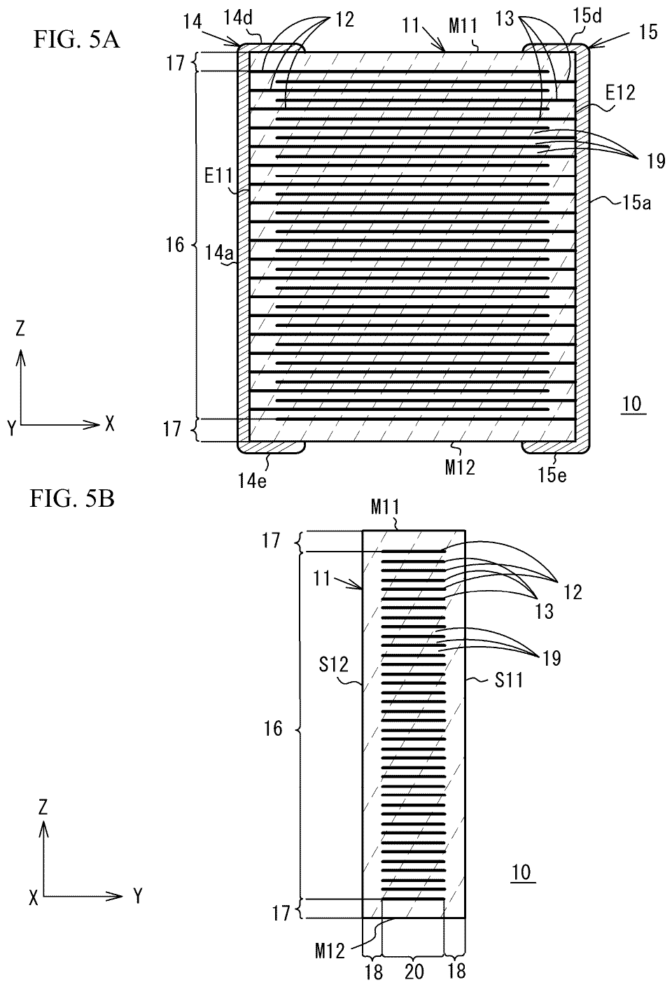

The external electrodes 14, 15 contain a metal material as a main component. An example of the metal material constituting the external electrodes 14, 15 is such as copper (Cu), nickel (Ni), tin (Sn), palladium (Pd), platinum (Pt), silver (Ag), gold (Au), or alloys of these. In this embodiment, the main component refers to the component with the highest content.

<Internal Structure> Next, the internal structure of the first multilayer ceramic capacitor 10 will be described with reference to FIG. 4 to FIG. 5B. FIG. 4 is a cross-sectional view of the first multilayer ceramic capacitor 10 taken along a line A1-A1 in FIG. 2. FIG. 5A is a cross-sectional view of the first multilayer ceramic capacitor 10 taken along a line A2-A2 in FIG. 2. FIG. 5B is a cross-sectional view of the first multilayer ceramic capacitor 10 taken along a line A3-A3 in FIG. 2. In FIG. 5B, the second external electrode 15 is omitted.

The ceramic body 11 has a multilayer portion 20 and a pair of margin portions 18. The multilayer portion 20 has a capacity forming portion 16 and a pair of cover portions 17. The capacity forming portion 16 includes a plurality of first and second internal electrodes 12, 13 alternately stacked with a plurality of ceramic layers 19 along the Z-axis direction. In this embodiment, the first internal electrode 12, the second internal electrode 13, and the ceramic layers 19 are each configured in a sheet shape extending along the X-Y plane. In addition, the number of layers of the first and second internal electrodes 12, 13 in each figure does not represent the actual number of layers.

The first and second internal electrodes 12, 13 are alternately arranged along the Z-axis direction so as to face each other in the Z-axis direction. The first and second internal electrodes 12, 13 face each other in the Z-axis direction in a facing section in the center of the X-axis and Y-axis directions. The first internal electrodes 12 corresponds to the first group, are drawn out from the facing section to one end face E11, and are connected to the first external electrode 14. The second internal electrodes 13 corresponds to the second group, are drawn out from the facing section to the other end face E12, and are connected to the second external electrode 15.

The first and second internal electrodes 12, 13 contain a metal material as a main component. The metal material is typically nickel (Ni), but other example is such as copper (Cu), palladium (Pd), platinum (Pt), silver (Ag), gold (Au), or alloys thereof. The metal material forming the internal electrodes 12, 13 may contain a low-melting point metal as an additive element, which has a melting point lower than that of the main component nickel (Ni). An example of such low-melting point metals is such as tin (Sn), zinc (Zn), aluminum (Al), gallium (Ga), or germanium (Ge). The internal electrodes 12, 13 may contain at least one of these low-melting point metals. By adding such a low-melting point metal, it is possible to improve the sintering property inside the ceramic body 11 and improve the insulation between the internal electrodes 12, 13.

With this configuration, when a voltage is applied between the external electrodes 14, 15 in the first multilayer ceramic capacitor 10, the voltage is applied to the plurality of ceramic layers 19 between the internal electrodes 12, 13 in the facing section. As a result, a charge corresponding to the voltage between the external electrodes 14, 15 is stored in the first multilayer ceramic capacitor 10.

In order to increase the electrostatic capacity of each of the ceramic layers 19 between the first and second internal electrodes 12, 13 in the multilayer portion 20, a dielectric ceramic with a high dielectric constant is used. An example of dielectric ceramics with a high dielectric constant is such as perovskite-structured materials containing barium (Ba) and titanium (Ti), such as barium titanate (BaTiO₃).

The dielectric ceramic may be a composition system such as strontium titanate (SrTiO₃), calcium titanate (CaTiO₃), magnesium titanate (MgTiO₃), calcium zirconate (CaZrO₃), calcium zirconate titanate (Ca(Zr,Ti)O₃), barium calcium zirconate titanate ((Ba,Ca)(Zr,Ti)O₃), barium zirconate (BaZrO₃), titanium oxide (TiO₂) or the like. Here, instead of adding a low melting point metal to the first and second internal electrodes 12, 13, or in addition to adding a low melting point metal to the first and second internal electrodes 12, 13, a low melting point metal may be added to the dielectric ceramic. The content of the low melting point metal and the effect of adding the low melting point metal are as described above, so a detailed explanation is omitted here.

The pair of cover portions 17 cover the capacity forming portion 16 from both sides in the Z-axis direction, which is the stacking direction. The cover portion 17 is sometimes referred to as a protective layer in the height direction. The cover portion 17 is composed, for example, of a multilayer structure of ceramic sheets extending along the XY plane. From the standpoint of suppressing internal stress, it is preferable that the dielectric ceramic that composes the cover portion 17 has the same composition as the ceramic layer 19.

The pair of margin portions 18 are formed along the Z-axis direction and cover the multilayer portion 20 from the Y-axis direction. The margin portions 18 are sometimes called width-direction protective layers. The margin portions 18 are attached to the surfaces of the multilayer portion 20 orthogonal to the Y-axis. For example, the margin portions 18 are formed of ceramic sheets and configured in a sheet shape extending along the X-Z plane. From the viewpoint of suppressing internal stress or the like, it is preferable that the dielectric ceramics constituting the margins 18 have the same composition as the ceramic layer 19.

<Second multilayer ceramic capacitor> The second multilayer ceramic capacitor 30 is the same as the first multilayer ceramic capacitor 10. In other words, the second multilayer ceramic capacitor 30 includes a ceramic body 31, the first external electrode 34, and the second external electrode 35. The ceramic body 31 is configured as a hexahedron having first and second main faces M31, M32 orthogonal to the Z axis, first and second end faces E31, E32 orthogonal to the X axis, and first and second side faces S31, S32 orthogonal to the Y axis.

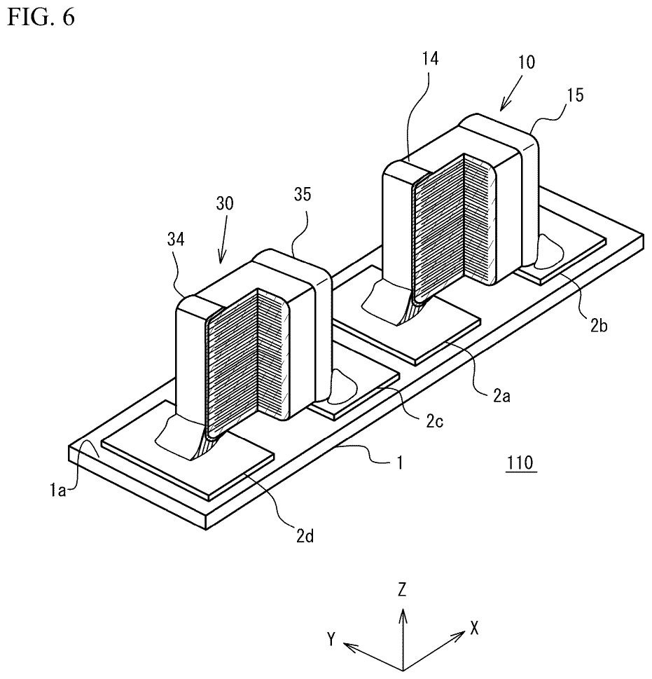

The ceramic body 31 also has a multilayer portion and a pair of margin portions, similar to the ceramic body 11, although none of them are given reference numbers. The multilayer portion has a capacity forming portion and the pair of cover portions 17. The capacity forming portion includes a plurality of first and second internal electrodes stacked alternately with a plurality of ceramic layers along the Z axis direction. Each of the components of the second multilayer ceramic capacitor 30 is the same as each of the components of the first multilayer ceramic capacitor 10 with the same names, and therefore detailed description thereof will be omitted here.

<Dimensional and positional relationships between the first and second multilayer ceramic capacitors> Now, referring to FIG. 6 and going back to FIG. 1A and FIG. 1B, the dimensional and positional relationships of the first and second multilayer ceramic capacitors 10 and 30 will be described. Note that FIG. 6 is a schematic diagram illustrating the arrangement of the first and second multilayer ceramic capacitors 10 and 30, and does not accurately represent the dimensional ratios of the various parts.

The first and second multilayer ceramic capacitors 10 and 30 are arranged so that their length directions coincide with the X-axis direction and their width directions are in the Y-axis direction. The center of the width of the first and second multilayer ceramic capacitors 10 and 30 are arranged so that they are approximately aligned in a straight line along the X-axis direction. The first external electrode 14 of the first multilayer ceramic capacitor 10 and the second external electrode 35 of the second multilayer ceramic capacitor 30 face each other along the X-axis direction.

Here, a gap S1 is provided between the first external electrode 14 of the first multilayer ceramic capacitor 10 and the second external electrode 35 of the second multilayer ceramic capacitor 30. The gap S1 is the shortest distance along the X-axis direction between the first external electrode 14 of the first multilayer ceramic capacitor 10 and the second external electrode 35 of the second multilayer ceramic capacitor 30. No other components are mounted between the first multilayer ceramic capacitor 10 and the second multilayer ceramic capacitor 30. Therefore, from the viewpoint of high-density mounting, it is preferable that the gap S1 is 0.3 mm or less, and more preferably 0.2 mm or less.

Here, the manner in which the first multilayer ceramic capacitor 10 is tilted will be considered. When the first multilayer ceramic capacitor 10 is tilted while mounted on the printed wiring board 1, it is assumed that the upper edge side of the first multilayer ceramic capacitor 10 is deflected in any direction along the Y-axis direction. The second multilayer ceramic capacitor 30 is also inclined in the same manner as the first multilayer ceramic capacitor 10 because the second multilayer ceramic capacitor 30 is the same as the first multilayer ceramic capacitor 10. In other words, the first multilayer ceramic capacitor 10 and the second multilayer ceramic capacitor 30 are not likely to be inclined in the X-axis direction in which they are adjacent to each other. Therefore, the first multilayer ceramic capacitor 10 and the second multilayer ceramic capacitor 30, which are adjacent to each other along the X-axis direction, are not likely to approach each other due to their respective inclinations. The gap S1 may be set in consideration of the fact that the first multilayer ceramic capacitor 10 and the second multilayer ceramic capacitor 30 are not likely to be in close proximity to each other.

In this embodiment, the first multilayer ceramic capacitor 10 and the second multilayer ceramic capacitor 30 are arranged such that their centers in the width direction are positioned approximately in a straight line along the X-axis direction, as described above. Therefore, as illustrated in FIG. 1D, when the first multilayer ceramic capacitor 10 and the second multilayer ceramic capacitor 30 are viewed along the X-axis direction from the first multilayer ceramic capacitor 10 side, only the first multilayer ceramic capacitor 10 is observed. However, such a positional relationship is only one example. As illustrated in FIG. 1E, the first multilayer ceramic capacitor 10 and the second multilayer ceramic capacitor 30 may be relatively shifted along the Y-axis direction within a range where at least a part of the second multilayer ceramic capacitor 30 overlaps with the first multilayer ceramic capacitor 10 when viewed along the X-axis direction. The direction in which they are relatively shifted along the Y-axis direction may be in any direction, as illustrated by an arrow 6 in FIG. 1E.

[Effect] In this embodiment, even if the first multilayer ceramic capacitor 10 or the second multilayer ceramic capacitor 30 is tilted in any direction along the Y-axis direction, contact between the two is avoided. In this embodiment, contact between the first external electrode 14 of the first multilayer ceramic capacitor 10 and the second external electrode 35 of the second multilayer ceramic capacitor 30, and thus the occurrence of a short circuit, can be avoided.

As described above, according to this embodiment, even if at least one of the first multilayer ceramic capacitor 10 and the second multilayer ceramic capacitor 30 is tilted, a short circuit between the first multilayer ceramic capacitor 10 and the second multilayer ceramic capacitor 30 is avoided. This makes it possible to narrow the distance between the first multilayer ceramic capacitor 10 and the second multilayer ceramic capacitor 30. In addition, the height T[10] of the first multilayer ceramic capacitor 10 and the height T[30] of the second multilayer ceramic capacitor 30 can be set large.

In this embodiment, the first multilayer ceramic capacitor 10 is located on the right side and the second multilayer ceramic capacitor 30 is located on the left side in FIG. 1B, but the positional relationship between the two is not limited to this. In other words, the first multilayer ceramic capacitor 10 may be located on the left side and the second multilayer ceramic capacitor 30 may be located on the right side.

In this embodiment, the first multilayer ceramic capacitor 10 and the second multilayer ceramic capacitor 30 are the same, but they do not necessarily have to be the same. The two multilayer ceramic capacitors may be adjacent to each other in the length direction so that one external electrode of one of them faces one external electrode of the other along the X-axis direction.

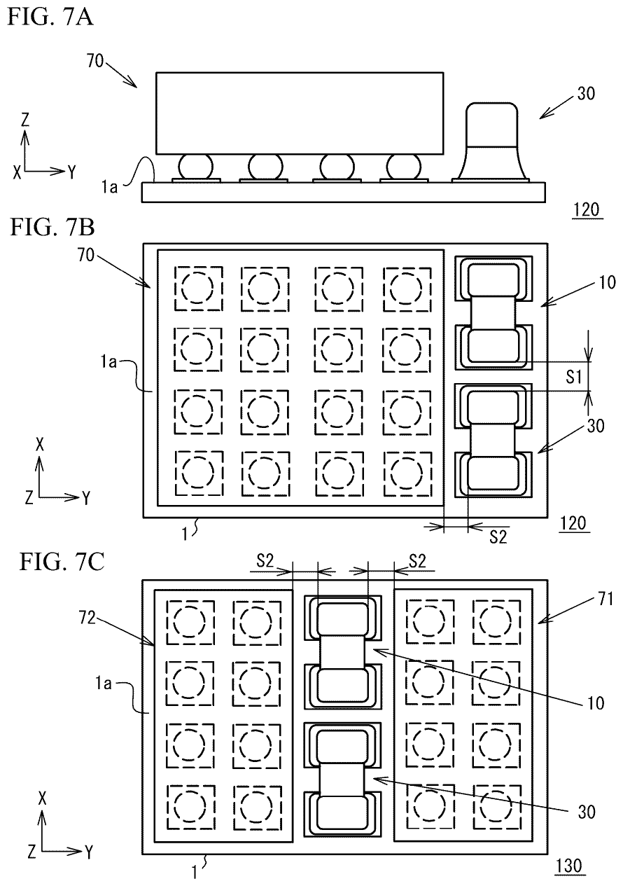

(Second embodiment) Next, the second embodiment will be described with reference to FIG. 7A and FIG. 7B. A circuit board 120 of the second embodiment includes an electronic component 70 as well as the first multilayer ceramic capacitor 10 and the second multilayer ceramic capacitor 30. The electronic component 70 is disposed adjacent to the first multilayer ceramic capacitor 10 and the second multilayer ceramic capacitor 30, which are adjacent to each other along the X-axis direction, in the width direction, that is, on one side along the Y direction.

The electronic component 70 is covered with an insulating coating. Therefore, even if the first multilayer ceramic capacitor 10 or the second multilayer ceramic capacitor 30 is tilted toward the electronic component 70 located on its side, a short circuit will not occur between the first multilayer ceramic capacitor 10 or the second multilayer ceramic capacitor 30 and the electronic component 70.

This allows the gap S2 between the first multilayer ceramic capacitor 10 and the electronic component 70 and the gap S2 between the second multilayer ceramic capacitor 30 and the electronic component 70 to be narrowed. It is also possible to set a large height for the first multilayer ceramic capacitor 10 and the second multilayer ceramic capacitor 30. From the viewpoint of high density mounting, the gap S2 is preferably set to 0.3 mm or less, more preferably 0.2 mm or less.

(Third embodiment) Next, the third embodiment will be described with reference to FIG. 7C. A circuit board 130 of the third embodiment includes an electronic component 71 and an electronic component 72, as well as the first multilayer ceramic capacitor 10 and the second multilayer ceramic capacitor 30. The electronic component 71 is disposed adjacent to the first multilayer ceramic capacitor 10 and the second multilayer ceramic capacitor 30, which are adjacent to each other along the X-axis direction, in the width direction, that is, on one side along the Y direction. The electronic component 72 is disposed so as to face the electronic component 71 across the first multilayer ceramic capacitor 10 and the second multilayer ceramic capacitor 30.

In other words, in this embodiment, electronic components are disposed on both sides of the first multilayer ceramic capacitor 10 and the second multilayer ceramic capacitor 30, which are adjacent to each other along the X-axis direction, in the width direction.

The electronic components 71 and 72 are covered with an insulating coating, similar to the electronic component 70 of the second embodiment. Therefore, even if the first multilayer ceramic capacitor 10 or the second multilayer ceramic capacitor 30 is tilted toward the electronic component 71 or 72 located on its side, a short circuit does not occur between the first multilayer ceramic capacitor 10 or the second multilayer ceramic capacitor 30 and the electronic component 71 or 72.

As a result, the gap S2 between the first multilayer ceramic capacitor 10 and the electronic component 71 and the gap S2 between the second multilayer ceramic capacitor 30 and the electronic component 71 can be narrowed. In addition, the gap S2 between the first multilayer ceramic capacitor 10 and the electronic component 72 and the gap S2 between the second multilayer ceramic capacitor 30 and the electronic component 72 can be narrowed. In addition, the height of the first multilayer ceramic capacitor 10 and the height of the second multilayer ceramic capacitor 30 can be set large.

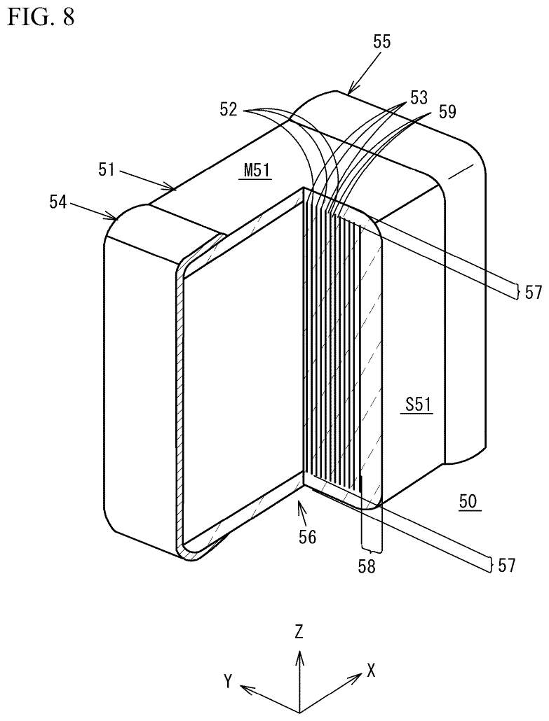

(Fourth embodiment) Next, a fourth embodiment will be described with reference to FIG. 8 to FIG. 10. As illustrated in FIG. 10, a first multilayer ceramic capacitor 50 and a second multilayer ceramic capacitor 61 are provided instead of the first multilayer ceramic capacitor 10 and the second multilayer ceramic capacitor 30 of the first embodiment.

The first multilayer ceramic capacitor 50 and the second multilayer ceramic capacitor 61 are the same. Therefore, the following description will mainly focus on the first multilayer ceramic capacitor 50.

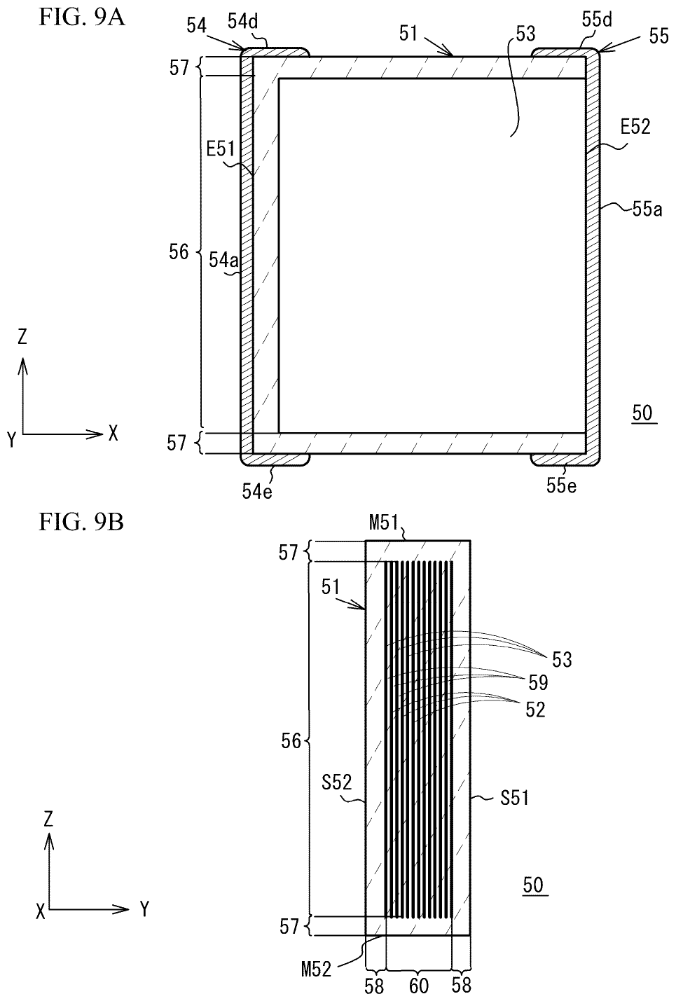

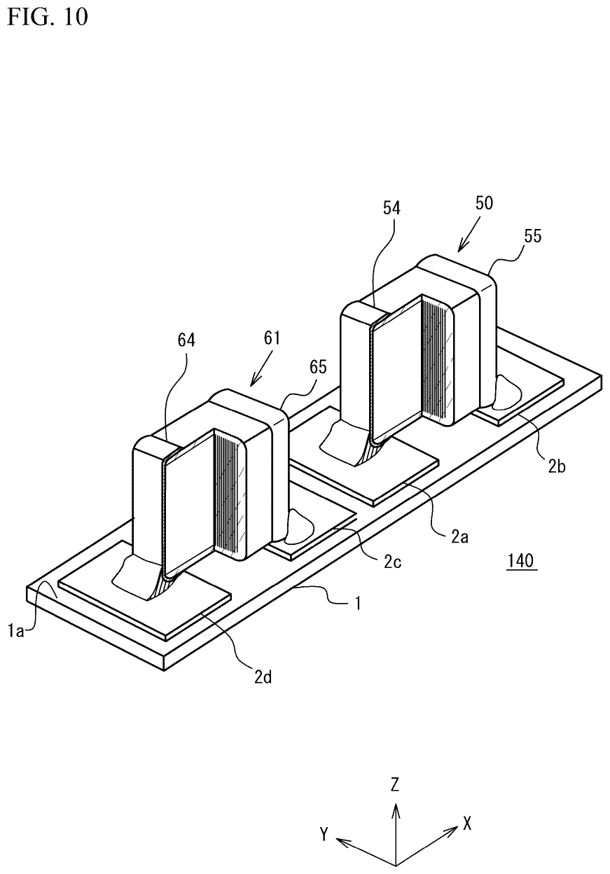

FIG. 8 is a cross-sectional view of the first multilayer ceramic capacitor 50 taken along a line corresponding to the line A1-A1 in FIG. 2. In other words, it is a cross-sectional view equivalent to the cross-sectional view of the first multilayer ceramic capacitor 10 of the first embodiment taken along the line A1-A1. FIG. 9A is a cross-sectional view of the first multilayer ceramic capacitor 50 taken along a line corresponding to the line A2-A2 in FIG. 2. In other words, it is a cross-sectional view equivalent to the cross-sectional view of the first multilayer ceramic capacitor 10 of the first embodiment taken along the line A2-A2. FIG. 9B is a cross-sectional view of the first multilayer ceramic capacitor 50 taken along a line corresponding to the line A3-A3 in FIG. 2. In other words, it is a cross-sectional view equivalent to the cross-sectional view of the first multilayer ceramic capacitor 10 of the first embodiment taken along the line A3-A3. FIG. 10 is a perspective view of the circuit board 140 illustrating the first multilayer ceramic capacitor 50 and the second multilayer ceramic capacitor 61 as partial cross sections. In FIG. 9B, the second external electrode 55 is omitted. FIG. 10 illustrates the layout of the first multilayer ceramic capacitor 50 and the second multilayer ceramic capacitor 61 in a schematic manner, and does not accurately represent the dimensional ratio of each part.

«External Shape» The external shape of the first multilayer ceramic capacitor 50 is generally the same as that of the first multilayer ceramic capacitor 10 of the first embodiment. That is, the first multilayer ceramic capacitor 50 includes a ceramic body 51, a first external electrode 54, and a second external electrode 55. The first external electrode 54 includes a first surface portion 54a, a second surface portion (not illustrated), a third surface portion (not illustrated), a fourth surface portion 54d, and a fifth surface portion 54e. The second external electrode 55 has a first surface portion 55a, a second surface portion (not illustrated), a third surface portion (not illustrated), a fourth surface portion 55d, and a fifth surface portion 55e. The first multilayer ceramic capacitor 50 has a first main face M51, a first side face S51, and the like. These components are common to the corresponding parts of the first multilayer ceramic capacitor 10 of the first embodiment, so detailed description thereof will be omitted here.

The length, the width, and the height of the first multilayer ceramic capacitor 50 are not illustrated, but are represented as the length L[50], width W[50], and height T[50], respectively, as in the first multilayer ceramic capacitor 10 of the first embodiment. The first multilayer ceramic capacitor 50 is a high-profile type in which the height T[50] is 1.3 times or more larger than the width W[50]. This point is also similar to the first multilayer ceramic capacitor 10 of the first embodiment.

<Internal Structure> Next, the internal structure of the first multilayer ceramic capacitor 50 in the second embodiment will be described with reference to FIG. 8 to FIG. 9B.

The ceramic body 51 has a multilayer portion 56 and a pair of cover portions 57. The multilayer portion 56 has a capacity forming portion 60 and a pair of margin portions 58. The capacity forming portion 60 includes a plurality of first and second internal electrodes 52, 53 that are alternately stacked with a plurality of ceramic layers 59 along the Y-axis direction. In this embodiment, the internal electrodes 52, 53 and the ceramic layers 59 are each configured in a sheet shape extending along the X-Z plane. The internal electrodes 52, 53 are stacked along the Y-axis direction and face each other in a direction parallel to the mounting surface 1a, so that the bonding area between each of the first internal electrodes 52 and the first external electrode 54 and the bonding area between each of the second internal electrodes 53 and the second external electrode 55 can be made large. This suppresses the capacity reduction due to poor contact, so-called capacity loss. Note that the number of layers of the first and second internal electrodes 52, 53 in each figure does not represent the actual number of layers.

The internal electrodes 52, 53 are alternately arranged along the Y-axis direction so as to face each other in the Y-axis direction. The internal electrodes 52, 53 face each other in the Y-axis direction in the central facing section in the X-axis direction and the Z-axis direction. The first internal electrodes 52 correspond to the first group, are drawn from the facing section to one end face E51, and are connected to the first external electrode 54. The second internal electrodes 53 correspond to the second group, are drawn from the facing section to the other end face E52, and are connected to the second external electrode 55.

The internal electrodes 52, 53 contain a metal material as a main component. A typical example of the metal material is such as nickel (Ni), and other example is such as copper (Cu), palladium (Pd), platinum (Pt), silver (Ag), gold (Au), or alloys thereof. The internal electrodes 52, 53 may contain a low-melting point metal, similar to the internal electrodes 12, 13 in the first embodiment.

With this configuration, when a voltage is applied between the external electrodes 54, 55 in the first multilayer ceramic capacitor 50, the voltage is applied to the multiple ceramic layers 59 between the internal electrodes 52, 53 in the facing section. As a result, in the second multilayer ceramic capacitor 30, a charge corresponding to the voltage between the external electrodes 54, 55 is stored.

In the multilayer portion 56, a dielectric ceramic with a high dielectric constant is used to increase the electrostatic capacity of each of the ceramic layers 59 between the internal electrodes 52, 53. An example of dielectric ceramics with a high dielectric constant is such as perovskite-structured materials containing barium (Ba) and titanium (Ti), such as barium titanate (BaTiO₃).

The dielectric ceramic may be a composition system such as strontium titanate (SrTiO₃), calcium titanate (CaTiO₃), magnesium titanate (MgTiO₃), calcium zirconate (CaZrO₃), calcium zirconate titanate (Ca(Zr,Ti)O₃), barium calcium zirconate titanate ((Ba,Ca)(Zr,Ti)O₃), barium zirconate (BaZrO₃), titanium oxide (TiO₂), or the like. As in the first embodiment, a low melting point metal can be added to the dielectric ceramic.

The pair of cover portions 57 are formed along the Y-axis direction and cover the multilayer portion 56 from the Z-axis direction. The cover portion 57 may also be referred to as a protective layer in the height direction. The cover portion 57 is attached later to a surface of the multilayer portion 56 orthogonal to the Z-axis. The cover portion 57 is formed, for example, by a multilayer structure of ceramic sheets extending along the X-Y plane. The dielectric ceramics constituting the cover portion 57 preferably have the same composition as the ceramic layer 59 from the viewpoint of suppressing internal stress.

The pair of margin portions 58 are formed along the Z-axis direction and cover the capacity forming portion 60 from the Y-axis direction. The margin portions 58 are sometimes called widthwise protective layers. The margin portions 58 are formed, for example, by ceramic sheets and are configured in a sheet shape extending along the X-Z plane. The dielectric ceramics constituting the margin portions 58 preferably have the same composition as the ceramic layer 59 from the viewpoint of suppressing internal stress.

Note that, for the second multilayer ceramic capacitor 61, different reference numbers from those of the first multilayer ceramic capacitor 50 are used for the components required for the following description. Specifically, a reference number 64 in FIG. 10 indicates the first external electrode, and a reference number 65 indicates the second external electrode 65.

As illustrated in FIG. 10, the first multilayer ceramic capacitor 50 and the second multilayer ceramic capacitor 61 are mounted on the printed wiring board 1 in the same manner as the first multilayer ceramic capacitor 10 and second multilayer ceramic capacitor 30 of the first embodiment illustrated in FIG. 1A, FIG. 1B and FIG. 6. That is, the center in the width direction of the first multilayer ceramic capacitor 50 and the center in the width direction of the second multilayer ceramic capacitor 61 are arranged so as to be positioned approximately on a straight line along the X-axis direction. The first external electrode 54 of the first multilayer ceramic capacitor 50 and the second external electrode 65 of the second multilayer ceramic capacitor 61 face each other along the X-axis direction.

As a result, even if the tall first multilayer ceramic capacitor 50 or the second multilayer ceramic capacitor 61 is tilted, contact between the external electrodes is avoided.

Note that electrostriction may occur in the first multilayer ceramic capacitor 50 or the second multilayer ceramic capacitor 61. The electrostriction may cause so-called acoustic noise. However, the stacking direction of the internal electrodes 52, 53 in the first multilayer ceramic capacitor 50 or the second multilayer ceramic capacitor 61 is along the Y-axis, which is the mounting direction, that is, orthogonal to the Z-axis direction. As a result, acoustic noise is suppressed in the first multilayer ceramic capacitor 50 or the second multilayer ceramic capacitor 61.

In this embodiment, the first multilayer ceramic capacitor 50 and the second multilayer ceramic capacitor 61, which are the same, are used, but one of them may be replaced with, for example, the first multilayer ceramic capacitor 10 of the first embodiment.

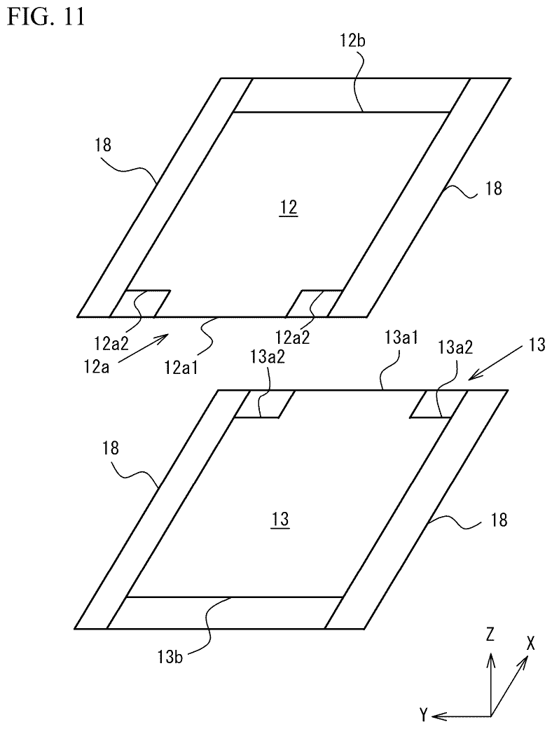

(Fifth embodiment) Next, the fifth embodiment will be described. The fifth embodiment differs from the first embodiment in the following points. Referring to FIG. 11, a partially disassembled state of the ceramic body of the first multilayer ceramic capacitor is illustrated. The fifth embodiment includes the first internal electrodes 12 and the second internal electrodes 13, as in the first embodiment, but the shapes of the electrodes are different. As the other parts are the same as those of the first embodiment, the following description will be given of the fifth embodiment with reference to the drawings for explaining the first embodiment as appropriate. In addition, the same reference numbers will be used for components common to the first embodiment.

As illustrated in FIG. 5A, the first internal electrodes 12 included in the first group are connected to the first external electrode 14, and the second internal electrodes 13 included in the second group are connected to the second external electrode 15.

Returning to FIG. 11, the first internal electrode 12 of this embodiment has a connection end 12a connected to the first external electrode 14, and an open end 12b located opposite the connection end 12a. A notch 12a2 is provided in the connection end 12a, forming a narrow portion 12a1. The width of the narrow portion 12a1 is narrower than the width dimension on the side closer to the open end 12b than the connection end 12a.

Similarly, the second internal electrode 13 of this embodiment has a connection end 13a connected to the second external electrode 15, and an open end 13b located opposite the connection end 13a. A notch 13a2 is provided in the connection end 13a, forming a narrow portion 13a1. The width of the narrow portion 13a1 is narrower than the width dimension on the side closer to the open end 13b than the connection end 13a.

With this configuration, for example, when the internal electrodes 12, 13 are made of Ni and the external electrodes 14, 15 are made of Cu, expansion of the internal electrodes 12, 13 due to the diffusion of Cu in the external electrodes 14, 15 can be prevented, and cracks can be prevented from occurring at the corners of the first multilayer ceramic capacitor. In particular, as explained in the first embodiment, even if a low-melting-point metal is added to the internal electrodes 12, 13 or the dielectric ceramic, the expansion of the internal electrodes 12, 13 can be avoided and the occurrence of cracks can be prevented.

In this fifth embodiment, the external shapes of the first multilayer ceramic capacitor 10 and the second multilayer ceramic capacitor 30 in the first embodiment, as well as the dimensional relationship and positional relationship between them, are maintained. Therefore, in the fifth embodiment, as in the first embodiment, short circuits between the first multilayer ceramic capacitor 10 and the second multilayer ceramic capacitor 30 are prevented.

(Modification) Next, a modification of the fifth embodiment will be explained. A circuit board 140 of the fifth embodiment maintains the basic configuration of the first embodiment, but has a modified shape for the internal electrodes 12, 13. In contrast, a circuit board 150 of this modified embodiment maintains the basic configuration of the fourth embodiment, but has a modified shape for the internal electrodes 52, 53.

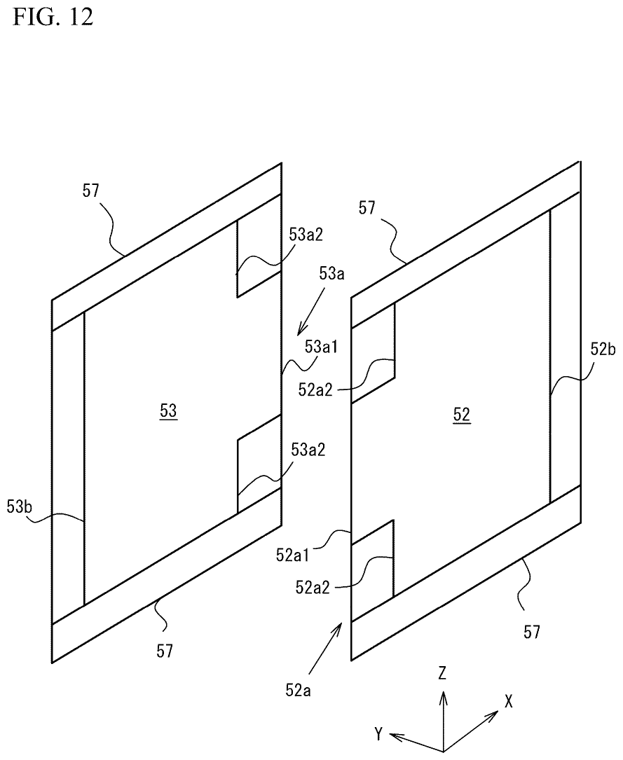

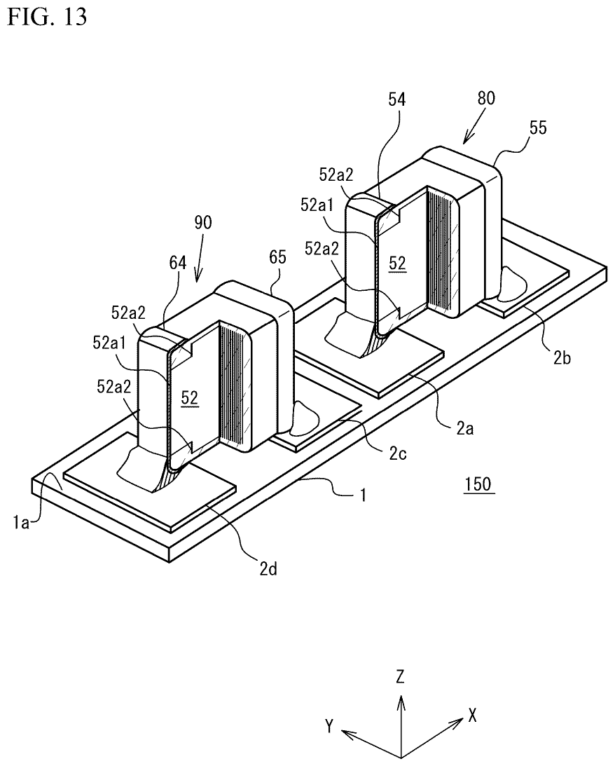

Referring to FIG. 12, the ceramic body of the first multilayer ceramic capacitor 80 and the second multilayer ceramic capacitor 90 (see FIG. 13) is partially disassembled. The first multilayer ceramic capacitor 80 and the second multilayer ceramic capacitor 90 correspond to the first multilayer ceramic capacitor 50 and the second multilayer ceramic capacitor 61 in the fourth embodiment, respectively.

The modified embodiment includes the first internal electrode 52 and the second internal electrode 53, as in the fourth embodiment, but their shapes are different. Since the other parts are the same as those in the fourth embodiment, the following description will be given of the modified embodiment of the fifth embodiment with reference to the drawings for explaining the fourth embodiment as appropriate. In addition, the same reference numbers will be used for the components common to the fourth embodiment.

The first internal electrodes 52 included in the first group, not illustrated, are connected to the first external electrode 54. As illustrated in FIG. 9A, the second internal electrodes 53 included in the second group are connected to the second external electrode 55.

Returning to FIG. 12, the first internal electrode 52 of this modified embodiment has a connection end 52a connected to the first external electrode 54, and an open end 52b located opposite the connection end 52a. A notch 52a2 is provided in the connection end 52a to form a narrow portion 52a1. The width of the narrow portion 52a1 is narrower than the width dimension of the side closer to the open end 52b than the connection end 52a. The width dimension of the first internal electrode 52 is the dimension along the Z-axis direction.

Similarly, the second internal electrode 53 of this modified embodiment has a connection end 53a connected to the second external electrode 55, and an open end 53b located opposite the connection end 53a. The connection end 53a has a notch 53a2 to form a narrow portion 53a1. The width of the narrow portion 53a1 is narrower than the width of the connection end 53a on the side closer to the open end 53b. The width of the second internal electrode 53 is also a dimension along the Z-axis direction.

By adopting such a configuration, for example, when the internal electrodes 52, 53 are made of Ni and the external electrodes 54, 55 are made of Cu, expansion of the internal electrodes 52, 53 due to diffusion of Cu in the external electrodes 54, 55 can be prevented, and cracks can be prevented from occurring at the corners of the first multilayer ceramic capacitor 90. In particular, as explained in the third embodiment, even if a low melting point metal is added to the internal electrodes 52, 53 or the dielectric ceramics, the expansion of the internal electrodes 12, 13 can be avoided and the occurrence of cracks can be prevented.

Even in such a modified embodiment, the external shape of the first multilayer ceramic capacitor 50 and the second multilayer ceramic capacitor 61 in the fourth embodiment, and the dimensional relationship and positional relationship between them are maintained. Therefore, even in the modified embodiment, short circuits between the first multilayer ceramic capacitor 80 and the second multilayer ceramic capacitor 90 are prevented, as in the fourth embodiment.

### EXAMPLE

(Example) Next, an example will be described together with a comparative example. In the example, the dimensions of each part of the first multilayer ceramic capacitor 10 and the second multilayer ceramic capacitor 30 in the circuit board 110 of the first embodiment are set to the values shown below. Four types of combinations of the first multilayer ceramic capacitor 10 and the second multilayer ceramic capacitor 30, patterns 1 to 4, were prepared.

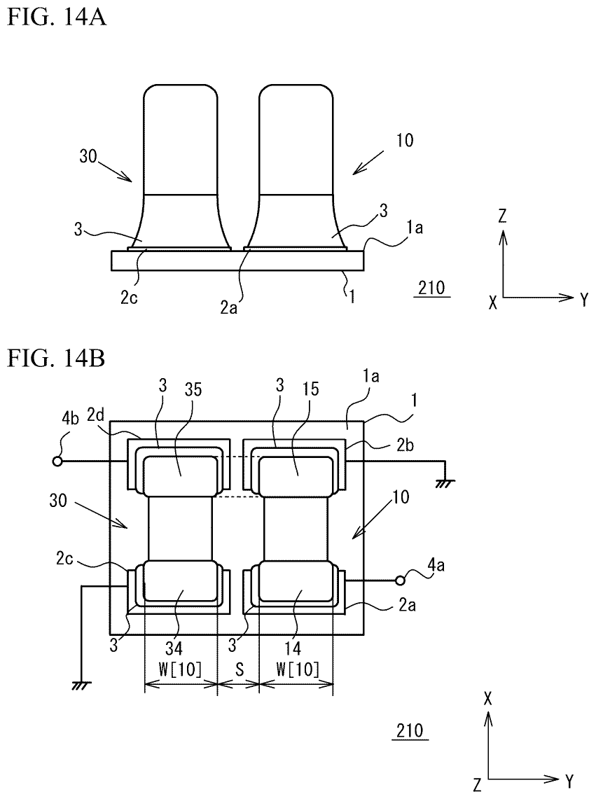

In the comparative example, as illustrated in FIG. 14A and FIG. 14B, the first multilayer ceramic capacitor 10 and the second multilayer ceramic capacitor 30 are arranged along the Y-axis direction. At this time, the positions of the first multilayer ceramic capacitor 10 and the second multilayer ceramic capacitor 30 along the X-axis direction are the same. In other words, the first external electrode 14 of the first multilayer ceramic capacitor 10 and the first external electrode 34 of the second multilayer ceramic capacitor 30 are adjacent to each other along the Y-axis direction. The second external electrode 15 of the first multilayer ceramic capacitor 10 and the second external electrode 35 of the second multilayer ceramic capacitor 30 are adjacent to each other along the Y-axis direction. The gap S is provided between the first external electrode 14 and the first external electrode 34, and between the second external electrode 15 and the second external electrode 35.

### Pattern 1

The first multilayer ceramic capacitor 10:
The length L[10]: 0.6 mm, the width W[10]: 0.3 mm, the height T[10]: 0.4 mm
The second multilayer ceramic capacitor 30:
Identical to the first multilayer ceramic, with the same dimensions
The gap S1:
0.1 mm

T[10]/W[10] in the pattern 1 is approximately 1.33, which satisfies the condition for the first multilayer ceramic capacitor 10 of the first embodiment that T[10] is 1.3 times or more W[10]. The second multilayer ceramic capacitor 30 also satisfies the same condition.

### Pattern 2

The first multilayer ceramic capacitor 10:
The length L[10]: 0.4 mm, the width W[10]: 0.2 mm, the height T[10]: 0.3 mm
The second multilayer ceramic capacitor 30:
The same as the first multilayer ceramic, with the same dimensions
The gap S1:
Same as the pattern 1.

T[10]/W[10] in the pattern 2 is 1.5, which satisfies the condition for the first multilayer ceramic capacitor 10 that T[10] is 1.3 times or more, and further 1.5 times or more, than W[10]. The second multilayer ceramic capacitor 30 also satisfies the same condition.

### Pattern 3

The first multilayer ceramic capacitor 10:
The length L[10]: 0.6 mm, the width W[10]: 0.3 mm, the height T[10]: 0.5 mm
The second multilayer ceramic capacitor 30:
Identical to the first multilayer ceramic, with the same dimensions
The gap S1:
Identical to the pattern 1.

T[10]/W[10] in the pattern 3 is approximately 1.67, which satisfies the condition for the first multilayer ceramic capacitor 10 that T[10] is 1.3 times or more, and further 1.5 times or more, the W[10]. The second multilayer ceramic capacitor 30 also satisfies the same condition.

### Pattern 4

The first multilayer ceramic capacitor 10:
The length L[10]: 1.0 mm, the width W[10]: 0.5 mm, the height T[10]: 0.8 mm
The second multilayer ceramic capacitor 30:
Same as the first multilayer ceramic, with the same dimensions
The gap S1:
Same as the pattern 1.

T[10]/W[10] in the pattern 4 is 1.6, which satisfies the condition for the first multilayer ceramic capacitor 10 that T[10] is 1.3 times or more, and even 1.5 times or more, of W[10]. The second multilayer ceramic capacitor 30 also satisfies the same condition.

### Comparative Example

The first multilayer ceramic capacitor 10:
The length L[10]: 0.6 mm, the width W[10]: 0.3 mm, the height T[10]: 0.4 mm
The gap S:
0.1 mm

T[10]/W[10] in the comparative example is approximately 1.33, which satisfies the condition of the first multilayer ceramic capacitor 10 of the first embodiment that T[10] is 1.3 times or more W[10].

[Test method] A predetermined number of samples are prepared for each of the patterns 1 to 4 of the example and the comparative example. Then, from among these, samples in which it is determined that at least one of the adjacent multilayer ceramic capacitors is tilted so as to approach each other while being aligned so that the width direction is the same are extracted. A voltage is applied between the first terminal 4a and the second terminal 4b for testing for the extracted samples, and the presence or absence of a short circuit is confirmed.

[Test results] In the patterns 1 to 4 of the example, no short circuit was confirmed in any of the samples.

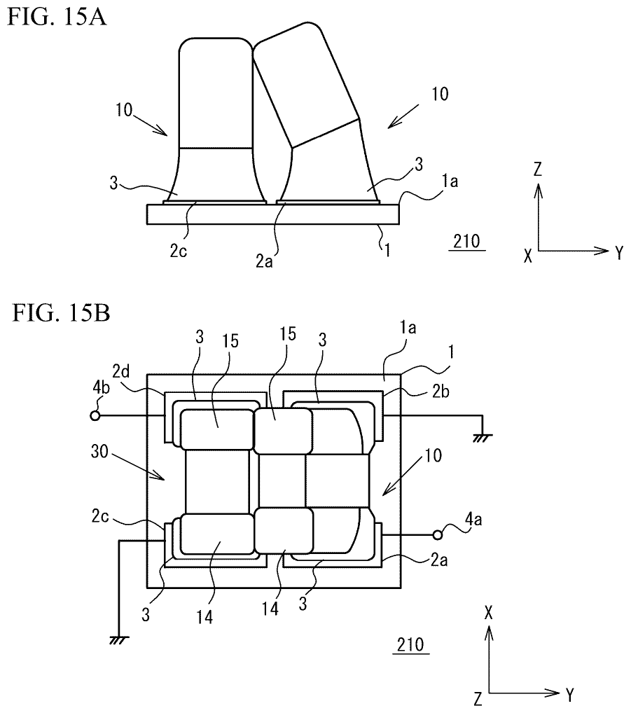

In the comparative example, the existence of a sample in which a short circuit occurred was confirmed. In such a sample, the tilt of the first multilayer ceramic capacitor 10 was confirmed. In the comparative example, as illustrated in FIG. 15A and FIG. 15B, when at least one of the first multilayer ceramic capacitor 10 and the second multilayer ceramic capacitor 30 is tilted so as to approach each other, the first external electrode 14 and the first external electrode 34 come into contact, and the second external electrode 15 and the second external electrode 35 come into contact. This causes a short circuit.

As described above, according to this embodiment, even when T[10] is 1.3 times or more than W[10], and even when T[10] is 1.5 times or more than W[10], the occurrence of a short circuit can be suppressed.

The external shape of the first multilayer ceramic capacitor 10 and the dimensional relationship and positional relationship with the second multilayer ceramic capacitor 30 in the first embodiment are maintained in the second to fifth embodiments and their modified examples. Therefore, it is considered that the occurrence of a short circuit can be similarly suppressed in all of the embodiments.

In the above embodiments, a multilayer ceramic capacitor has been described as an example of a multilayer ceramic electronic component, but the present invention is not limited to this. For example, the configuration of each of the above embodiments can also be applied to other multilayer ceramic electronic components, such as varistors and thermistors.

Although the embodiments of the present invention have been described in detail, it is to be understood that the various change, substitutions, and alterations could be made hereto without departing from the spirit and scope of the invention.

1. A circuit board comprising:
a board; and
a plurality of multilayer ceramic electronic devices mounted on a mounting surface of the board,
wherein when a direction along a first axis is defined as a height direction, a direction along a second axis orthogonal to a direction along the first axis is defined as a width direction, and a direction along a third axis orthogonal to the direction along the first axis and the direction along the second axis is defined as a length direction, of the plurality of multilayer ceramic electronic devices, at least a first multilayer ceramic electronic device and a second multilayer ceramic electronic device have a first external electrode at a first end in the length direction and a second external electrode at a second end in the length direction,
wherein a height dimension of the first multilayer ceramic electronic device is 1.3 times or more larger than a width dimension or a length dimension of the first multilayer ceramic electronic device, and a height dimension of the second multilayer ceramic electronic device is 1.3 times or more larger than a width dimension or a length dimension of the second multilayer ceramic electronic device, and
wherein the first ceramic electronic device and the second multilayer ceramic electronic device are arranged on the mounting surface in a state in which the respective height directions of the first ceramic electronic device and the second multilayer ceramic electronic device are orthogonal to the mounting surface, the length directions of the first ceramic electronic device and the second multilayer ceramic electronic device are in the same direction, and one of the first external electrode and the second external electrode of the first multilayer ceramic electronic device and one of the first external electrode and the second external electrode of the second multilayer ceramic electronic device are adjacent to each other along the length direction and opposed to each other along the length direction.

2. The circuit board as claimed in claim 1,
wherein the first external electrode and the second external electrode provided on the first ceramic electronic device and the second multilayer ceramic electronic device, respectively, each have a predetermined length along the length direction, and
wherein another electronic component is mounted adjacent to at least one side along the width direction of the first ceramic multilayer electronic device and the second multilayer ceramic electronic device which are adjacently arranged in the length direction and is covered with an insulating coating.

3. The circuit board as claimed in claim 2,
wherein other electronic components, each covered with an insulating coating, are mounted on both sides along the width direction of the first multilayer ceramic device and the second multilayer ceramic electronic device that are adjacent to each other in the length direction.

4. The circuit board as claimed in claim 1,
wherein at least one of the height dimension of the first multilayer ceramic electronic device and the height dimension of the second multilayer ceramic electronic device is 1.5 times or more larger than the width dimension or the length dimension thereof.

5. The circuit board as claimed in claim 1,
wherein at least one of internal electrodes provided in a ceramic body of the first multilayer ceramic electronic device and internal electrodes provided in a ceramic body of the second multilayer ceramic electronic device are stacked in a direction along the first axis so as to face each other in the direction along the first axis.

6. The circuit board as claimed in claim 5,
wherein the internal electrodes stacked in the direction along the first axis include a first internal electrode connected to the first external electrode and a second internal electrode connected to the second external electrode,
wherein the first internal electrode has a connection end connected to the first external electrode and an open end located opposite the connection end, and the connection end has a narrow portion whose width dimension is narrower than the width dimension of a portion closer to the open end than the connection end, and
wherein the second internal electrode has a connection end connected to the second external electrode and an open end located opposite the connection end, and the connection end has a narrow portion whose width dimension is narrower than the width dimension of a portion closer to the open end than the connection end.

7. The circuit board as claimed in claim 1,
wherein at least one of internal electrodes provided in a ceramic body of the first multilayer ceramic electronic device and internal electrodes provided in a ceramic body of the second multilayer ceramic electronic device are stacked in a direction along the second axis so as to face each other in the direction along the second axis.

8. The circuit board as claimed in claim 7,
wherein the internal electrodes stacked in the direction along the second axis include a first internal electrode connected to the first external electrode and a second internal electrode connected to the second external electrode,
wherein the first internal electrode has a connection end connected to the first external electrode and an open end located opposite the connection end, and the connection end has a narrow portion whose width dimension is narrower than the width dimension of a portion closer to the open end than the connection end,
wherein the second internal electrode has a connection end connected to the second external electrode and an open end located opposite the connection end, and the connection end has a narrow portion whose width dimension is narrower than the width dimension of a portion closer to the open end than the connection end.

9. The circuit board as claimed in claim 6,
wherein the internal electrodes or dielectric layers formed between the internal electrodes contain a low melting point metal.

10. The circuit board as claimed in claim 8,
wherein the internal electrodes or dielectric layers formed between the internal electrodes contain a low melting point metal.
